(19) United States
(12) Patent Application Publication
(10) Pub. No.: US 2007/0042609 A1
(43) Pub. Date: Feb. 22, 2007

(54) Molecular caulk: a pore sealant for ultra-low k dielectrics

(76) Inventors: John J. Senkevich, Rolla, MO (US); Toh-Ming Lu, Loudonville, NY (US)

Correspondence Address: HESLIN ROTHENBERG FARLEY & MESITI PC, 5 COLUMBIA CIRCLE, ALBANY, NY, 12203, US

(21) Appl. No.: 11/413,527

(22) Filed: Apr. 28, 2006

Related U.S. Application Data
(60) Provisional application No. 60/675,763, filed on Apr. 28, 2005.

(51) Int. Cl. H01L 21/31; H01L 21/4763

(52) U.S. Cl. 438/778; 438/623; 438/622; 438/790

(57) ABSTRACT

Methods of use of parylene based polymers with porous ultra-low κ dielectric materials and use of parylene barriers in integrated circuit fabrication are presented.

### CROSS-REFERENCE TO RELATED APPLICATIONS

This application claims priority from U.S. Provisional Application Ser. No. 60/675,763, filed Apr. 28, 2005, the entire contents of which are incorporated herein by reference.

### FIELD OF THE INVENTION

The invention relates to methods of use of parylene-based polymers with porous ultra-low k dielectric materials and use of parylene barriers in integrated circuit fabrication.

### BACKGROUND OF THE INVENTION

In designing future gigascale integrated circuits (IC), resistive capacitance RC delay is an increasingly important issue. RC delay, which represents the signal propagation delay through interconnects in microelectronic integrated circuits is, becoming a governing factor in controlling the overall chip speed. New materials are being explored as replacements for SiO₂ as low dielectric constant (low-κ) interlayer dielectrics (ILD) for reducing the RC delay. Future generation ICs need a low-κ material with a bulk dielectric constant of less than 2. It is believed that the introduction of porosity is necessary to satisfy the low-κ requirements of the IC industry.

The introduction of porosity into an ILD results in a number of other undesirable properties such as a reduction in mechanical strength and susceptibility to penetration or diffusion of precursor molecules, chemical solvents, plasma species, and the like during chemical vapor deposition (CVD), electroless deposition, electrochemical deposition, and super critical fluid deposition processes. A need exists for pore sealants and methods of use thereof with porous ILDs that overcome at least one of the aforementioned deficiencies.

### SUMMARY OF THE INVENTION

An aspect of the present invention relates to a method for sealing pores of a porous substrate against penetration of moisture, or solvents or aqueous solutions used in electroless processing or wet chemical processing of the substrate, or against penetration of precursor gases used in a metallization process. The method comprises: providing a porous substrate having an average pore diameter size in a range from 0.5 nm to 5 nm; and depositing onto the porous substrate, a parylene-containing polymeric film having a typical thickness in a range from 1.1 nm to 3.5 nm.

A second aspect of the present invention relates to a method for preventing penetration of metal atoms or ions, or precursors thereof, from a metallization layer during the deposition of the metallization layer onto a porous substrate. The method comprises: depositing a parylene containing polymeric film having a typical thickness in a range from 1.1 nm to 3.5 nm onto a porous substrate; and depositing the metallization layer from a metal or metallorganic precursor onto the polymeric film.

A third aspect of the present invention relates to a method for controlling the effective dielectric constant of a porous interlayer dielectric (ILD). The method comprises: depositing a parylene containing polymeric film having a typical thickness in a range from 1.1 nm to 3.5 nm at a pressure selected from 1 millitorr to 8 millitorr and in the presence of a carrier gas selected from argon, helium, and nitrogen onto the porous ILD; and depositing a metallization layer from a metal or metallorganic precursor onto the polymeric film.

A fourth aspect of the present invention relates to an integrated circuit. The integrate circuit comprises: one or more integrated circuit components; and an interlayer dielectric (ILD) having directly thereon (1) a parylene containing polymeric film having a typical thickness in a range from 1.1 nm to 3.5 nm and (2) a metal layer over the polymeric film.

### BRIEF DESCRIPTION OF THE DRAWINGS

FIG. 1 depicts RBS spectra of copper deposition on two different substrates, in accordance with the present invention;

FIG. 2 depicts a plot of equivalent amount of copper deposited as a function of molecular caulk thickness (nm), in accordance with the present invention;

FIG. 3 depicts RBS spectra of cobalt deposited on three different substrates, in accordance with the present invention;

FIG. 4 depicts a ⁴He 4.28 MeV ion beam backscattering spectra of a stack having the Molecular Caulk (MC) and a stack without the MC, in accordance with the present invention;

FIG. 5 depicts a plot ⁴He 4.28 MeV ion beam backscattering data for a stack having the MC and a bare stack as a function of MC precursor pressure, in accordance with the present invention;

FIG. 6A depicts an AFM image of a bare stack, in accordance with present invention;

FIG. 6b depicts an AFM image of a stack having the MC, in accordance with present invention;

FIG. 6C depicts a plot of root mean square (rms) roughness (nm) as a function of MC thickness (nm), in accordance with the present invention;

FIG. 6D depicts a plot of lateral correlation length as a function (nm) of MC thickness (nm), in accordance with the present invention;

FIG. 7 depicts a plot of concentration of MC inside a porous substrate as a function of depth in the porous substrate, in accordance with the present invention;

FIG. 8 depicts a profile % MC in a pore sealed porous MSQ as function of depth inside the MSQ at varying deposition pressures, in accordance with present invention;

FIG. 9 depicts a plot of MC deposition rate (A/min) as a function of MC (mTorr) pressure with and without a carrier gas, in accordance with the present invention; and

FIG. 10 depicts a profile % MC in a pore sealed porous MSQ as function of depth inside the MSQ at varying deposition pressures with and without Ar as the carrier gas, in accordance with present invention.

### DETAILED DESCRIPTION OF THE INVENTION

Throughout this specification the terms and substituents are defined when first introduced and retain their definitions.

A xerogel is a dried out open structure or a dried out compact macromolecular gel, which has passed a gel stage during preparation. Typically, it is a solid formed from a gel by drying with unhindered shrinkage. Examples include silica gel, rubber, gelatin, and the like.

An aerogel is a porous silica-based solid formed by replacing the liquid of a gel with a gas. It is typically a foam-like material having density values of 3 mg/cm³ or less.

An integrated circuit (IC) component is an element of an IC. Examples of an IC component include, but are not limited to, an interconnected semiconductor device such as a transistor or a resistor; a copper interconnect; an aluminum interconnect; a porous or non-porous low k dielectric material; an insulating layer, a barrier layer, a wafer comprising a semiconducting material such as silicon, doped silicon, silicon on sapphire, gallium arsenide; and the like.

The term effective dielectric constant is intended to mean the dielectric constant of a structure comprising more than one material.

The terms “halogen” or “halo” refer to fluorine, chlorine, bromine, and iodine.

Alkyl is intended to include linear, branched, or cyclic hydrocarbon structures and combinations thereof. Lower alkyl refers to alkyl groups of from 1 to 6 carbon atoms. Examples of lower alkyl groups include methyl, ethyl, propyl, isopropyl, butyl, s- and t-butyl and the like. Preferred alkyl groups are those of C₂₀ or below; more preferred are C₁-C₈ alkyl. Cycloalkyl is a subset of alkyl and includes cyclic hydrocarbon groups of from 3 to 8 carbon atoms. Examples of cycloalkyl groups include cyclopropyl, cyclobutyl, cyclopentyl, cyclohexyl, norbornyl, or other bridged systems and the like.

Acyl refers to groups of from 1 to 8 carbon atoms of a straight, branched, cyclic configuration, saturated, unsaturated and aromatic and combinations thereof, attached to the parent structure through a carbonyl functionality. One or more carbons in the acyl residue may be replaced by nitrogen, oxygen or sulfur as long as the point of attachment to the parent remains at the carbonyl. Examples include acetyl, benzoyl, propionyl, isobutyryl, t-butoxycarbonyl, benzyloxycarbonyl and the like. Lower-acyl refers to groups containing one to four carbons.

Alkoxy or alkoxyl refers to groups of from 1 to 8 carbon atoms of a straight, branched, cyclic configuration and combinations thereof attached to the parent structure through an oxygen. Examples include methoxy, ethoxy, propoxy, isopropoxy, cyclopropyloxy, cyclohexyloxy and the like. Lower-alkoxy refers to groups containing one to four carbons. Oxaalkyl refers to alkyl residues in which one or more carbons (and their associated hydrogens) have been replaced by oxygen. Examples include methoxypropoxy, 3,6,9-trioxadecyl and the like. The term oxaalkyl is intended as it is understood in the art [see Naming and Indexing of Chemical Substances for Chemical Abstracts, published by the American Chemical Society, ¶196, but without the restriction of ¶127(a)], i.e. it refers to compounds in which the oxygen is bonded via a single bond to its adjacent atoms (forming ether bonds); it does not refer to doubly bonded oxygen, as would be found in carbonyl groups.

A method for sealing pores of a porous substrate against penetration of moisture, or solvents or aqueous solutions used in electroless processing or wet chemical processing of the substrate, or against penetration of precursor molecules, chemical solvents, or plasma species used in a metallization process is presented in accordance with present invention. The method comprises providing a porous substrate having an average pore diameter size in a range from 0.5 nm to 10 nm. Then depositing onto the porous substrate, a parylene containing polymeric film having a thickness on the same order to twice the order of the average pore diameter size of the substrate.

Examples of the porous substrate include but are not limited to hydrosilsesquioxane (HSQ), methyl silsesquioxane (MSQ), a SiLK resin, an anodized aluminum oxide, a xerogel, an aerogel, and a chemical vapor deposited carbon-doped oxide. A SiLk resin is an aromatic hydrocarbon polymer containing phenylene and carbonyl group in the main chain. Typically, the porous substrate is an ILD. The porous substrates typically have an average pore diameter size in a range from 0.5 nm to 10 nm. The pore size may vary in ranges from a lower limit of 0.1, 1, or 2 nm to an upper limit of 8, 9, or 10 nm. All ranges of the average pore diameter size are inclusive and combinable.

The polymeric film of the present invention is comprised of poly(p-xylylene) (also termed parylene-N). The monomer unit is composed of an aromatic group with methylene groups attached at the para positions, see below: 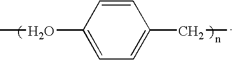
The use of the parylene-N monomer unit supra to form the polymeric film is not meant to limit the kinds of monomers and subsequently polymeric films that may be used in an embodiment of the present invention. Substituted parylene-N monomer units that polymerize to form polymeric films that fall within the parylene class of polymers may be used in accordance with the present invention.

Substituents of the parylene-N monomer units include but are not limited to halogen, alkyl, acyl, cyano, carboalkoxy (also referred to as alkoxycarbonyl), hydroxy, amino, thio, alkoxy, and alkylamino.

Examples of substituted parylene-N monomers are listed below:

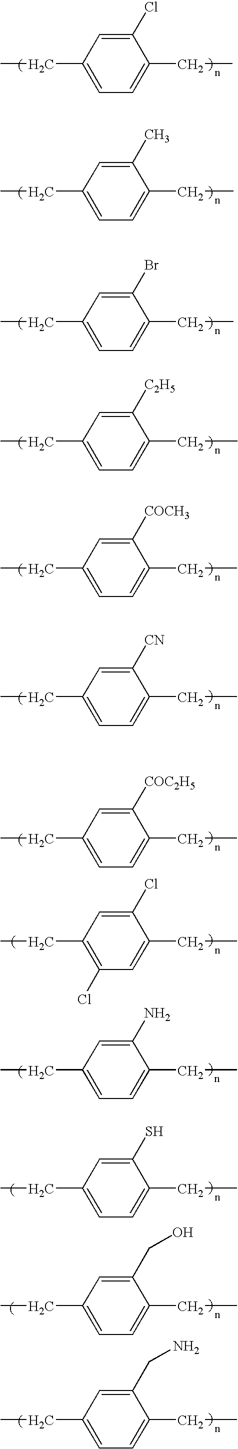

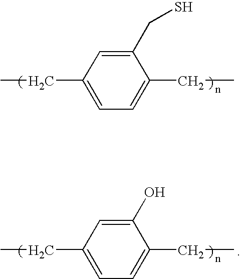

Additional examples of monomer units that comprise or partially comprise the parylene containing polymeric film that may be used in an embodiment of the present invention include phenylene vinyl, phenylene ethynylene, 1,4-methylene naphthalene, 2,6-methylene naphthalene, 1,4-vinylene naphthalene, 2,6-vinylene naphthalene, 1,4-ethynylene naphthalene, 2,6-ethynylene naphthalene, and substituted counterparts.

The parylene containing polymeric film is deposited onto the substrate using the Gorham method described by W. Gorham, J. Polym. Sci., Part A-1, 4 3027 (1966), the entire contents of which is incorporated herein by reference. The polymeric film has a thickness on the order of the average pore diameter size of the substrate. The deposited polymeric film thickness is typically in range from 1.1 nm to 3.5 nm. The film thickness may vary in ranges from a lower limit of 0.5, 1.0, 1.5 nm to an upper limit of 2, 2.5, or 3 nm. All ranges of the film thickness are inclusive and combinable. When the film is deposited onto the porous substrate, it conformally coats the substrate, i.e., it is a conformal coating. From herein the parylene containing polymeric film will be referred to as Molecular Caulking or Molecular Caulk (MC).

During CVD or atomic layer deposition (ALD) of a barrier layer, the gas-phase precursors have a tendency to infiltrate the porous dielectric or porous substrate. It has been shown that copper is deposited inside the porous dielectric rather than on the surface during CVD as described by C. Jezewski, W. Lanford, J. J. Senkevich, D. Ye, and T.-M. Lu, Chem. Vapor Dep. 9(6) 305-7 (2003), the entire contents of which are incorporated herein by reference. The copper precursor penetrated the interconnected porous-MSQ dielectric and selectively deposited at the interface between the MSQ film and the silicon substrate. The deposition was quantitatively measured by Rutherford back scattering (RBS) and observed by scanning electron microscopy (SEM). RBS has monolayer sensitivity to Cu and Co precursors and therefore was used to quantitatively measure the amount of metallorganic penetrant or metal deposited.

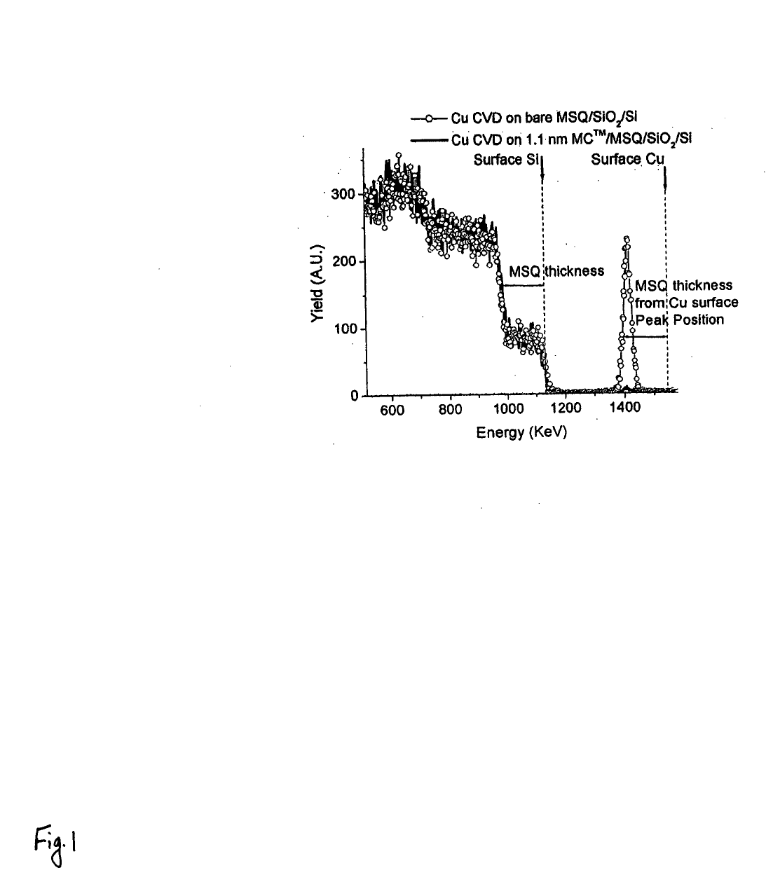

FIG. 1 depicts RBS spectra of copper deposition on two different substrates in accordance with the present invention. The spectra are plotted with yield in atomic units (A.U.) as a function of energy in kili-electron volts (KeV). Referring to FIG. 1, the spectrum is taken after copper deposition on a bare MSQ/SiO₂/Si and 1.1 nm MC/MSQ/Si sample. The arrows labeled “surface copper” and “surface silicon” indicate the kinematic energy of backscattering from copper and silicon at the surface. The observed peak at ˜1400 keV indicates that copper is deposited at the interface between the MSQ and the SiO₂/Si substrate. The double arrows indicate the thickness of the MSQ film as determined by the width of the silicon signal in MSQ. The double arrow length also corresponds with the signal peak of penetrated copper.

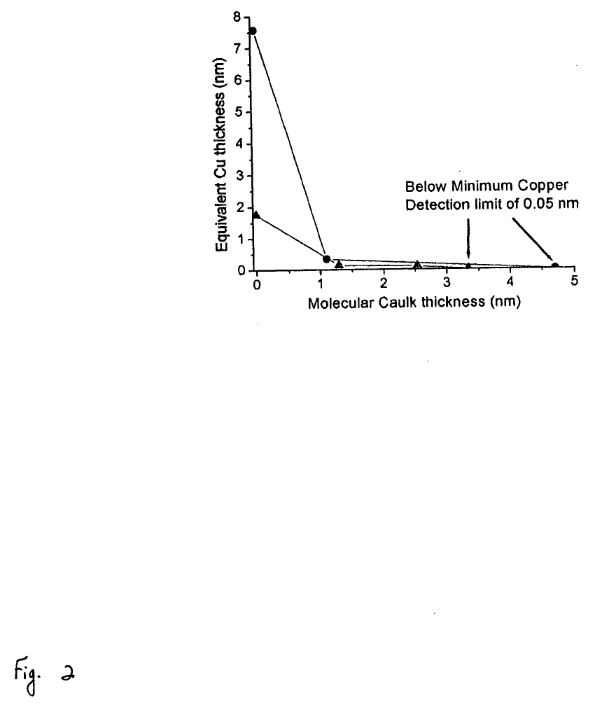

FIG. 2 depicts a plot of equivalent amount of copper deposited as a function of molecular caulk thickness (nm) in accordance with the present invention. Referring to FIG. 2, RBS was used to determine the equivalent amount of copper deposited by CVD at the MSQ/SiO₂ interface as a function of MC thickness. Data from two separate experiments are shown, which demonstrates that 1.1 nm of MC resulted in a 96% reduction of copper penetration during CVD. After 3.5 nm of MC deposition, the copper penetration dropped below the 0.05 nm detection limit of RBS. Reactor modifications, including precursor and purge gas inlet lines, resulted in different growth rates of the two experiments, but the MC thickness sufficient to prevent copper penetration was consistent. The two data sets, circles and triangles, are from experiments before and after reactor altercations respectively.

The copper precursor penetration into the MSQ/SiO₂/Si was measured as a result of selective deposition at the MSQ/SiO₂/Si interface but not at the MSQ/SiO₂/Si surface as described by C. Jezeweski et al. referenced above. If the MC deposition passivates the MSQ/SiO₂ interface, there would be no deposition to signify the penetration of the copper precursor. A non-selective metallorganic precursor Co₂(CO)₈ was chosen to provide further evidence that MC conformally coats and seals the pores of the porous substrate. Cobalt CVD is non-selective and readily grows on top of the MC layer. Deposition was ˜0.5 nm/min at 60° C. (precursor sublimation was room at temperature), a temperature where cobalt deposition is surface-reaction controlled and thus expected to grow at the surface and penetrate the porous MSQ.

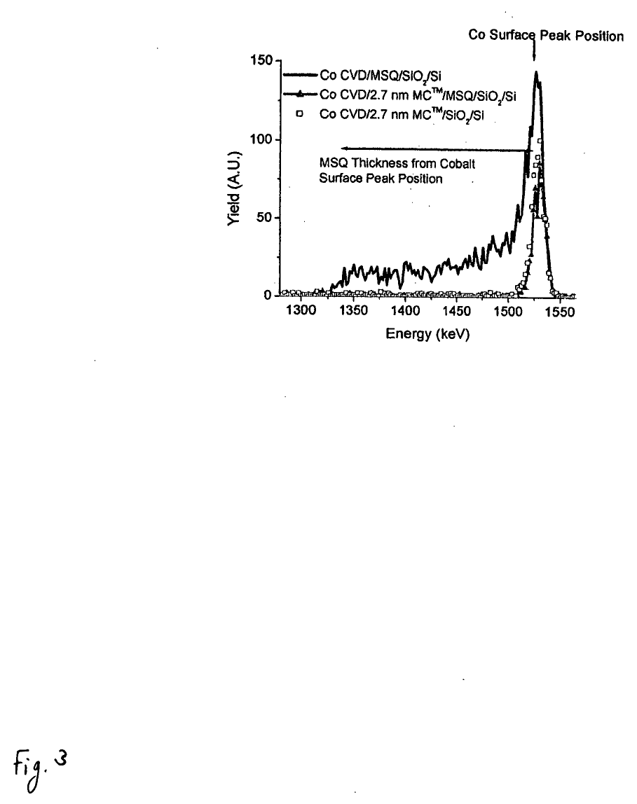

FIG. 3 depicts RBS spectra of cobalt deposited on three different substrates in accordance with the present invention. The spectra are plotted with yield in atomic units (A.U.) as a function of energy in kili-electron volts (KeV). Referring to FIG. 3, RBS spectra of the three samples are presented: Co/2.7 nm MC/SiO₂/Si, Co/2.7 nm MC/MSQ/SiO₂/Si, and Co/bare MSQ/SiO₂/Si. The bare MSQ shows penetration of cobalt supported by the long tail of the cobalt surface peak, while the other samples have only surface deposition. The width of penetrated cobalt is consistent with the silicon width (thickness) in MSQ and shows cobalt penetrates completely through the MSQ film when MC is not used as a conformal pore sealant. The Co/2.7 nm MC/SiO₂/Si and Co/2.7 nm MC/MSQ/SiO₂/Si samples show cobalt deposition only on the surface of the MC and no penetration into the porous MSQ/SiO₂/Si substrate.

Capacitance measurements showed that the dielectric constant of a MSQ (500 nm)/SiO₂/Si film covered with 3.7 nm of MC had essentially the same dielectric constant as the bare MSQ/SiO₂/Si film. The effective dielectric constant of the low k stack was calculated from the slope of the measured accumulation capacitance vs. capacitor area. The measured dielectric constant of porous MSQ was 2.26, this increased to 2.30 after an annealed MC coated dielectric film. The ˜1.7% increase in dielectric constant after annealing at 250° C. was less than the sample-to-sample variation in capacitor area. The MSQ film used was thicker than what would be typically used. However, the measurements still show that the MC material itself is low k and the penetration of the MC into the MSQ film has a minimal deleterious effect on the k effective.

MC thickness was determined by Variable Angle Spectroscopic Ellipsometry (VASE) on SiO₂. VASE is an indirect method measurement method that was used for quantitative comparison. The MC thickness was determined by VASE on the native oxide of Si rather than on MSQ/SiO₂/Si since it is difficult to measure a 1 nm thick MC film on 200 nm-500 nm MSQ. During CVD, precursor gases can readily diffuse into the porous material and therefore the penetration of the MC into the porous dielectric was expected.

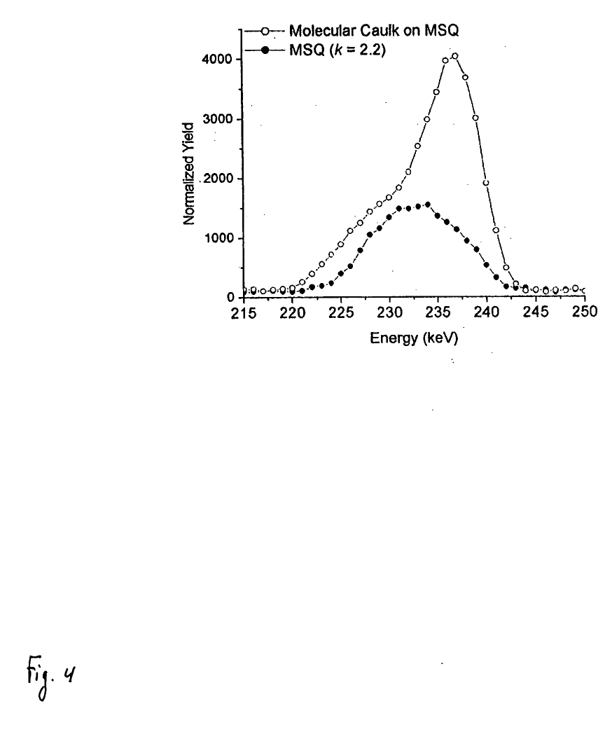

FIG. 4 depicts a ⁴He 4.28 MeV ion beam backscattering spectra of a stack having the MC and a stack without the MC in accordance with the present invention. Referring to FIG. 4, the spectra are plotted with normalized yield as a function of energy (KeV). The quantitative measure of deposited film content in/on the porous MSQ/SiO₂/Si stack was determined by adding a stoichiometric percentage of hydrogen (C₈H₈) to the measured carbon content as determined by ⁴He ion beam backscattering analysis at 4.28 MeV or 5.75 MeV. The MC was deposited at 6.4 mTorr and ˜40 nm thick, which is observed as the high energy peak. The view has been expanded to show only the carbon region of spectra. The silicon substrate contribution has been subtracted from both spectra to emphasize relative carbon content in each sample. The tail on the low energy side of the MC spectrum is due to penetration. A representative example of a MC porous-MSQ dielectric is shown in terms of ¹²C resonance.

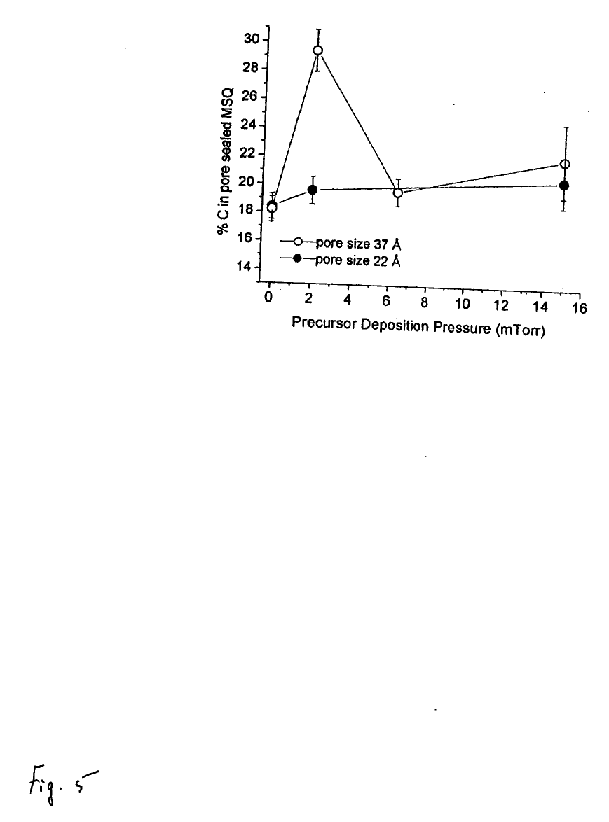

FIG. 5 depicts a plot ⁴He 4.28 MeV ion beam backscattering data for a stack having the MC and a bare stack as a function of MC precursor pressure in accordance with the present invention. The MC was deposited at 2 to 15 mTorr at ˜40 nm of thickness. Referring to FIG. 5, measurements of carbon content were made on bare MSQ/SiO₂/Si and MC/MSQ/SiO₂/Si samples, where the MC was deposited at various pressures. Also, two different MSQ dielectrics were used, k=2.2 (average pore size 2.2 nm) and k=2.0 (average pore size 3.7 nm). Amorphous carbon (H-Square, Sunnyvale, Calif.) was used as a standard. Amorphous carbon is dense and has a mirror smooth surface.

No detectable bulk contamination was determined by RBS, and hydrogen depth profiling showed no bulk contamination of hydrogen at a detection limit of ˜0.1%. Given that bare MSQ/SiO₂/Si and MC/MSQ/SiO₂/Si are approximately the same thickness, the carbon content of MC/MSQ/SiO₂/Si was obtained by comparing the carbon contents in both films using backscattering geometry and cross-section data determined by the amorphous carbon standard. An increase in carbon content of 1.54×10¹⁷ At/cm² was found for the 3.5 nm MC/540 nm MSQ/SiO₂Si film. Adding a stoichiometric quantity of hydrogen (C₈H₈) brings the total density to 3.08×10¹⁷ At/cm². The bulk density of MC is 1.02×10²³ At/cm³, so an equivalent MC thickness of approximately 30 nm was deposited in/on MSQ/SiO₂/Si. Qualitatively, it can be seen that the carbon content of the front two thirds of the film has a statistically significant increase in carbon content.

To estimate the increase in dielectric constant, a uniform penetration of MC layer was assumed. One MSQ film was 540 nm thick and contained 50% porosity (relative to SiO₂), so an MC equivalent thickness of 30 nm evenly distributed through the MSQ film would fill 11.1% of the porosity. An upper bound calculation of the composite film dielectric constant can be found by adding the contribution of components in parallel:
kₜₒₜ=k₁P₁+k₂P₂+k₃P₃
where kₜₒₜ, k₁, k₂, and k₃ are the dielectric constants of the total film, air MC and the dense MSQ respectively. P₁, P₂, and P₃ are the respective fractions of air, MC, and the dense MSQ. An increase of approximately 4% in the dielectric constant should be expected assuming a dielectric constant of 2.65 of the MC material. A capacitance-determined dielectric constant increase of 1.5+−3.3% for a 3.7 nm thick MC/MSQ/SiO₂/Si is consistent with these results.

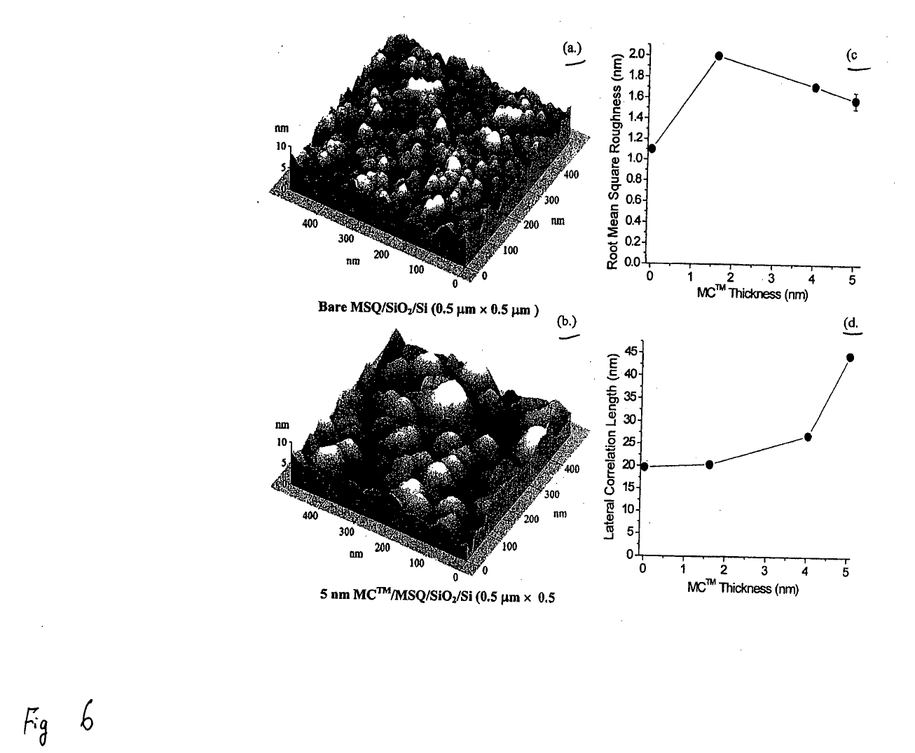

FIG. 6A and FIG. 6b depict AFM images of a bare stack and a stack with the MC respectively, in accordance with present invention. Referring to FIGS. 6A and 6B, the bare stack is MSQ/SiO₂/Si and the MC stack is MC/SiO₂/Si. Surface roughness was measured by AFM and quantitative information about surface morphology was extracted from a height-height correlation function as described by Y.-P. Zhao, G.-C. Wang, and T.-M. Lu, Experimental Methods in the Physical Sciences: Characterization of Amorphous and Crystalline Rough Surfaces: Principles and Applications, Vo. 37, p. 18, Academic Press (2000), the entire contents of which are incorporated herein by reference.

FIG. 6C depicts a plot of root mean square (rms) roughness (nm) as a function of MC thickness (nm) in accordance with the present invention.

FIG. 6D depicts a plot of lateral correlation length as a function (nm) of MC thickness (nm) in accordance with the present invention.

FIGS. 6A and 6B show the AFM thickness needed to prevent penetration and the RMS surface roughness is 0.62 nm greater than the bare MSQ/SiO₂/Si sample. The morphology after deposition indicates an initial increase in roughness followed by an apparent smoothing as deposition proceeds (See FIG. 6C). The lateral correlation length continues to increase with deposition thickness and rises from an initial 20 nm for the bare MSQ/SiO₂/Si to 44.6 nm in the 5 nm thick MC/SiO₂/Si coated sample. The lateral correlation length indicates that as the film grows there is some longer range smoothing. The MC deposition is envisioned to be able to smooth rough sidewalls generated after the RIE of the porous dielectrics. The lateral correlation length is roughly the wavelength of fluctuation of the surface. The lateral correlation length changes are evident in the AFM images of bare MSQ (see FIG. 6A) and 5 nm MC coated MSQ (see FIG. 6b) by an overall increase in surface feature size.

It has been shown that no deposition occurs on an air-exposed Cu surface as described by J. J. Senkevich, C. J. Wiegand, G-R. Yang, T.-M. Lu “Selective Deposition of Ultra-thin Parylene-N films on Dielectrics versus Copper Surfaces”, Chemical Vapor Deposition, Vol. 10, p. 237, (2004) and K. M. Vaeth and K. F. Jensen, Chem. Mater., 12 1305 (2000), the entire contents both of which are incorporated herein by reference. It was shown that 335 nm of polymer grew on a silicon substrate before any growth occurred on copper. Selectivity is a highly desired quality of the free radical polymerization process used here. For Dual Damascene structures in the back-end-of-the-line processes there would be no deposition on the copper via. Only the dielectric would be coated and there would be no series contribution to the Ohmic contact from the MC film. This would alleviate the need to etch back the dielectric liner and therefore reduce the number of processing steps.

A method for controlling the effective dielectric constant of a porous interlayer dielectric (ILD) is presented in accordance with the present invention. The method comprises depositing a parylene containing polymeric film having a typical thickness in a range from 1.1 nm to 3.5 nm at a pressure selected from 1 millitorr to 8 millitorr and in the presence of a carrier gas selected from argon, helium, and nitrogen onto the porous ILD; and depositing a metallization layer from a metal or metallorganic precursor onto the polymeric film. The aforementioned carrier gases are not meant to limit the types or kinds gases that may be used as carrier gases in an embodiment of the present invention. The artisan will recognize that any inert gas can be used as a carrier gas in accordance with the present invention.

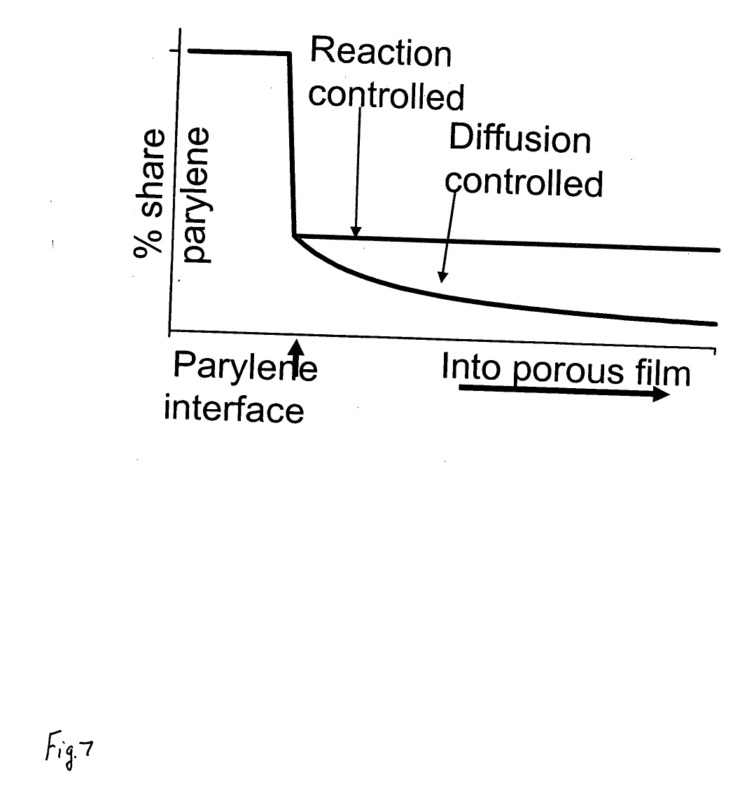

FIG. 7 depicts a plot of concentration of MC inside a porous substrate as a function of depth in the porous substrate in accordance with the present invention. It has been demonstrated that the penetration of the MC in a porous dielectric or porous substrate decays almost exponentially with depth from the exposed surface as described by C. Jezewski, W. A. Langford, C. J. Wiegand, J. J. Senkevich, T.-M. Lu, Semiconductor International 27(5), 56 (2004), the entire contents of which are incorporated herein by reference. Referring to FIG. 7, the concentration profile shows that the concentration of MC in the pores decays in thickness as the depth into the dielectric increases.

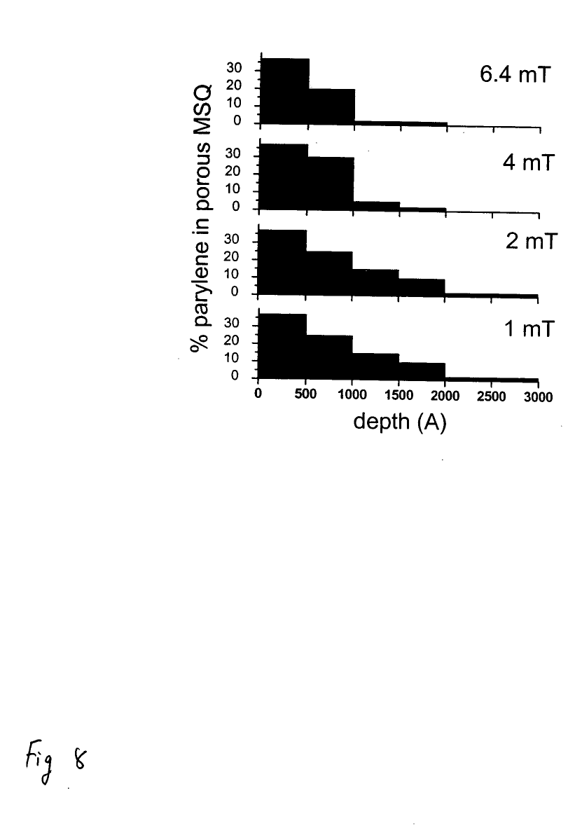

FIG. 8 depicts a profile % MC in a pore sealed porous MSQ as function of depth inside the MSQ at varying deposition pressures in accordance with present invention. The percent MC penetration was calculated from Nuclear Reaction Analysis (NRA) data comparing bare MSQ and MC pore sealed MSQ where the extra carbon is attributed to the MC. Referring to FIG. 8, the porous MSQ used had a porosity of 49% and MC occupies more than half of the pore space available near the top of the surface but significantly decreases deeper into the dielectric. The profile demonstrates that a lower pressures of 1 or 2 mTorr the penetration is high, but decreases at higher pressures.

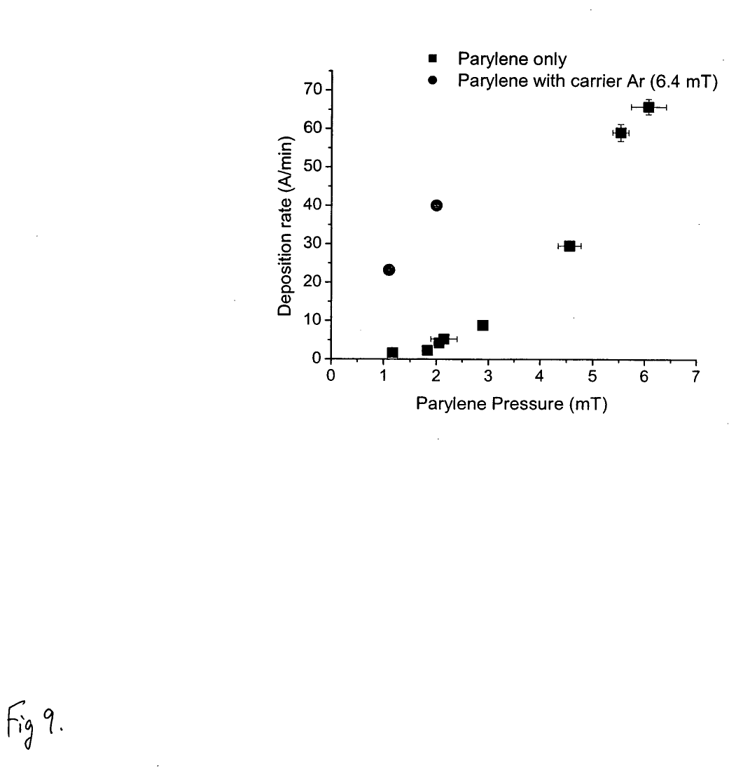

FIG. 9 depicts a plot of MC deposition rate (A/min) as a function of MC (mTorr) pressure with and without a carrier gas in accordance with the present invention. Referring to FIG. 9, increasing the pressures results in a higher deposition rate of the MC. The deposition rate governs the time required for sealing the pores of the porous dielectric. At high pressures, the deposition rate increases and the pores seal off quicker thus reducing the time allowed for the MC to diffuse into the porous dielectric. The reduction in time for pore sealing outweighs the increase in the concentration gradient at higher pressures. Thus the penetration of the MC into the dielectric decreases with increased pressures.

An argon carrier gas was added to the MC monomer vapors at a fixed mass flow rate that was maintained by a needle valve. The mass flow of Ar used resulted in an overpressure of 6.4 mTorr in the deposition chamber. The deposition rate of the MC increased the addition of Ar carrier gas. More so than without the carrier gas. An increased deposition rate was also observed even when the carrier gas was introduced in the line before the furnace and therefore had the same temperature of the MC monomer.

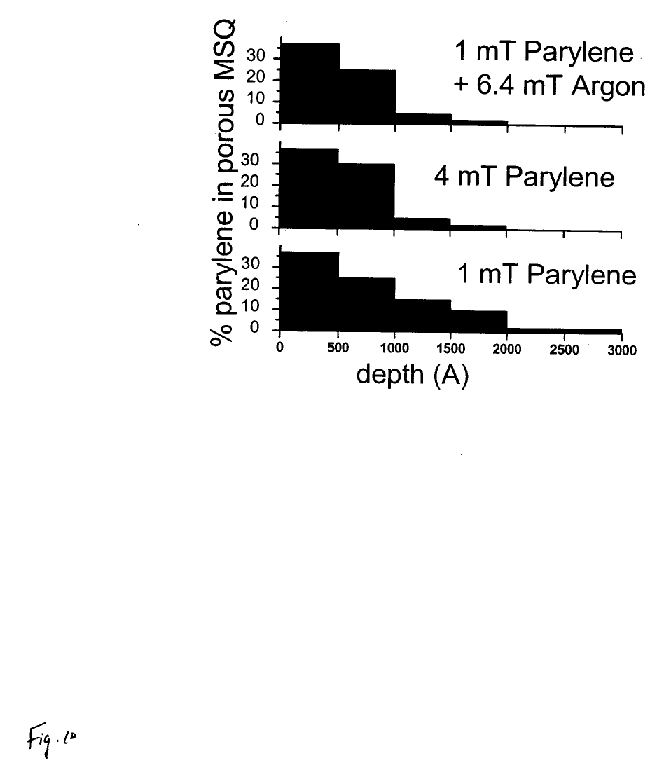

FIG. 10 depicts a profile % MC in a pore sealed porous MSQ as function of depth inside the MSQ at varying deposition pressures with and without Ar as the carrier gas in accordance with present invention. The Ar partial pressure and the MC monomer partial pressure were maintained at 6.4 mTorr and 1 mTorr respectively. The deposition rate was ˜2.3 nm/min. Referring to FIG. 10, the penetration of the MC inside the porous dielectric was slightly higher than the case where deposition was performed with 6.4 mTorr MC monomer pressure but much lower than the case where the monomer pressure was 1 mTorr. The deposition rate for 1 mTorr MC monomer pressure with 6.4 mTorr Ar carrier gas was similar to that of 4 mTorr MC monomer pressure with no carrier gas. Likewise, the penetration of the MC for both examples was similar. The deposition rate of the MC directly affects the penetration of the MC in the porous dielectric.

CVD of MC is an effective sealant for porous low-k dielectrics or other porous substrates. There is some penetration of the MC into the porous dielectric during deposition, which results in an increase in the effective dielectric constant of the dielectric material. The penetration and hence the change in the effective dielectric constant can be controlled by deposition the pressure and the use of a carrier gas. Higher deposition pressure results in lower penetration of the MC into the porous MSQ and hence the least change in the effective dielectric constant. A higher deposition rate can be achieved by the use of a carrier gas such as Argon. MC penetration into the porous MSQ where deposition was performed with a carrier gas to raise the system pressure resulted in an increase in the deposition rate and subsequently the least change in the effective dielectric constant.

An integrated circuit (IC) is presented in accordance with the present invention. The IC comprises: one or more integrated circuit components; and an interlayer dielectric (ILD) having directly thereon (1) a parylene containing polymeric film having a typical thickness in a range from 1.1 nm to 3.5 nm and (2) a metal layer over the polymeric film. The term “over” is meant to intend a position above, higher than, or upon the surface of. The term “over” is not meant to be limited to direct physical contact with. For example when the metal layer is over the polymeric film, the metal layer may be in direct contact with polymeric film or the metal layer and the polymeric film may have another material interposed.

### EXPERIMENTAL

For some studies presented, the porous MSQ film was deposited by spin coating and went through a series of baking stations before the final cure in an N₂ ambient at 420° C. The resulting films contained 50% porosity and the pores were interconnected. Pore diameter sizes were in a range from 0.5 nm to 4 nm. The average pore diameter size was 1.5 nm. MSQ has a nominal stoichiometry of SiO_{1.5}(CH)_{0.5}.

For other studies, the ultra low-k porous MSQ was provided by Texas Instruments and Motorola. The substrate was 300 nm of porous MSQ on thermally grown 6.8 nm of SiO₂ on n-doped Si (100) with a resistivity of 10 Ω-cm. The MSQ films were 49% porous and had interconnected pores with an average pore diameter of 4.1 nm. The MSQ has a nominal stoichiometry of SiO_{1.5}(CH)_{0.5}.

Copper (Cu) CVD experiments were done via Cu^{II}(tmhd)₂ and H₂ in a vertical, low pressure, warm-wall reactor. The precursor bubbler was held at a constant temperature of 127.5±0.6° C. and delivered with 15 sccm of argon (Ar) carrier gas. The substrate was kept at 217±5° C., and the chamber walls and the precursor transfer lines were all held at 150±5° C. The total pressure of Ar, H₂, and precursor was approximately 2 torr. The deposition time for all experiments were 30 min. unless otherwise noted. Bare MSQ and several MC/MSQ films of varying MC thickness were placed side-by-side on the substrate heater in each experiment. Further details on the Cu CVD process employed is described in journal article by C. Jezewski, W. Lanford, J. J. Senkevich, D. Ye, and T.-M. Lu, Chem. Vapor Dep. 9(6) 305-7 (2003), the entire contents of which are incorporated herein by reference.

Cobalt deposition experiments were performed in a different vertical, low pressure, warm-wall reactor. Cobalt carbonyl dimer [Co₂(CO)₈] was sublimed at room temperature. The substrate was kept at 60° C.±2° C. and the deposition time was 2 minutes. No carrier or purge gas was used. The deposition pressure was approximately 18 mTorr and maintained by a mechanical vacuum pump. Bare MSQ and several MC/MSQ films of varying MC thickness were placed side-by-side on the substrate heater in each experiment.

MC films were deposited using the Gorham method as referenced earlier. The reactor consisted of a sublimation furnace, a pyrolysis furnace, and a bell jar type deposition chamber. Base pressure in the deposition chamber was at mid 10⁻⁶ Torr. During growth, the deposition chamber pressure was at 1-6 mTorr yielding deposition rates between 0.07-0.84 nm/min. A detailed description of the reactor and deposition process is provided by J. B. Fortin, and T.-M. Lu, J. Vac. Sce. Technol. A, 18(5) 2459 (2000) and J. B. Fortin and T.-M. Lu, Chem. Mater. 14 1945 (2002), the entire contents of both which are incorporated herein by reference.

Briefly, the precursor [2.2]paracyclophane was sublimed at a temperature of 155° C. and the pressure controlled by a heated valve and measured by a heated capacitance in the deposition chamber. The sublimed precursor flew into a high temperature region (650° C.) of the reactor inlet where it was quantitatively cleaved into two p-xylylene monomers by vapor phase pyrolysis. These reactive intermediates were then transported to a room temperature deposition chamber where upon physisorption, a free radical polymerization took place. Linear chains of poly(p-xylylene) with un-terminated end groups were formed.

Bulk poly(p-xylylene) has an average dielectric constant of 2.65 perpendicular to the plane of the film. Ultra-thin (10-50 A) parylene-containing polymeric films were deposited. Silicon (Si) 100 50 Ω-cm substrates were rinsed in ethanol, followed by deionized water, blown dry with nitrogen and then placed side-by-side with the porous MSQ in the deposition reactor. After deposition, samples were annealed in forming gas at 250° C. for 30 minutes.

The deposited film thickness was measured by a variable angle spectroscopy ellipsometer (VASE, J. A. Wollam, Lincoln, NB) on silicon samples. VASE measurement interpretation is difficult on MSQ films, so thickness measurements were used from the silicon wafers and assumed similar growth on the MSQ films. The thickness of the MC was determined by using the Cauchy coefficients of poly-para-xylyene (Aₙ=1.6, Bₙ=0.01) or an index of refraction of 1.458 at 634.1 nm. The depth profile of parylene-N in porous MSQ was obtained by Nuclear Reaction Analysis (NRA) of ¹²C, since parylene-N is [C₈H₈]ₙ. ¹²C exhibits a strong (α,α) elastic scattering resonance in the energy region ˜4.3 MeV. At this energy the cross section is more than 2 orders higher than the Rutherford cross section and therefore small changes in carbon concentration can be detected. The analysis of NRA data was performed similar to the analysis described by C. Jezewski, W. A. Langford, C. J. Wiegand, J. J. Senkevich, T.-M. Lu, Semiconductor International 27(5), 56 (2004), the entire contents of which are incorporated herein by reference.

Copper growth was characterized by Rutherford backscattering spectroscopy (RBS) with the 4.0 MeV Dynamitron accelerator at the Ion Beam Laboratory: Department of Physics, University at Albany. Measurements were made with 2.0 MeV ⁴He particles. The RBS determined areal density was converted into an equivalent thickness by dividing by the bulk atomic density of copper 8.45×10²² atoms/cm³. Spectra were collected with a 20 mm² area beam spot, 2-4 μC of charge, and with 2 nA of current. Ion beam backscattering using the 5.75 MeV ⁴He elastic nuclear resonance of ¹²C was undertaken at the same facility.

Two samples were chosen from the k study: 540 nm MSQ/5 nm SiO₂/Si (control sample) and 250° C. annealed 3.7 nm MC/540 nm MSQ/5 nm SiO₂/Si. Top aluminum dots of 0.5, 1, and 1.5 mm diameter were electron beam evaporated via a shadow mask. In order to get good Ohmic contact at the backside of the silicon wafer, 300 nm of aluminum was sputter deposited. The capacitance-voltage (C-V) characteristics of the Al/low-k (stack)/5 nm SiO₂/Si structures were measured with a HP 4280A 1 MHz Capacitance meter/CV plotter. At least five measurements were performed for each capacitor size for each sample.

Surface morphology was measured using an atomic force microscope, AFM, (AutoProbe CP) made by Park Scientific Instruments, TM Microscope. A triangular silicon cantilever with silicon conical tip (Veeco Metrology Group) was used in non-contact mode to measure the surface topography. The tip radius of curvature is <10 nm and had a half apex angle of 12°.

What is claimed is:

1. A method for sealing pores of a porous substrate against penetration of moisture, or solvents or aqueous solutions used in electroless processing or wet chemical processing of the substrate, or against penetration of precursor gases used in a metallization process, the method comprising:
providing a porous substrate having an average pore diameter size in a range from 0.5 nm to 5 nm; and
depositing onto the porous substrate, a parylene containing polymeric film having a typical thickness in a range from 1.1 nm to 3.5 nm.

2. A method according to claim 1, wherein the polymeric film comprises a first layer disposed on the porous substrate and a second layer disposed in the porous substrate.

3. A method according to claim 1, wherein the porous substrate is an interlayer dielectric.

4. A method according to claim 1, wherein the polymeric film comprises repeating units derived from p-xylylene, phenylene vinyl, phenylene ethynylene, 1,4-methylene naphthalene, 2,6-methylene naphthalene, 1,4-vinylene naphthalene, 2,6-vinylene naphthalene, 1,4-ethynylene naphthalene, 2,6-ethynylene naphthalene, and substituted counterparts.

5. A method according to claim 1, wherein the polymeric film comprises repeating units selected from:

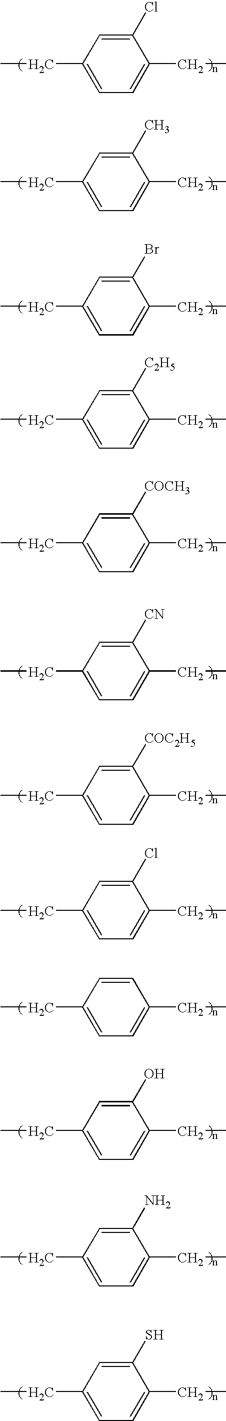

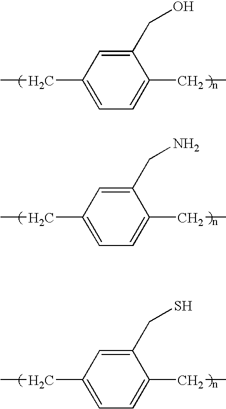

6. A method according to claim 1, wherein the porous substrate is selected from the group consisting of hydrosilsesquioxane, a methyl silsesquioxane, an anodized aluminum oxide, a xerogel, an aerogel, and a chemical vapor deposited carbon-doped oxide.

7. A method according to claim 1, wherein the polymeric film has a thickness in a range from 2.5 nm to 5 nm.

8. A method according to claim 1, wherein the polymeric film has a thickness in a range from 1 to 20 nm.

9. A method according to claim 1, wherein the parylene containing polymeric film is deposited at a pressure selected from 1 millitorr to 8 millitorr.

10. A method according to claim 1, wherein the parylene containing polymeric film is deposited in the presence of a carrier gas selected from argon, helium, and nitrogen.

11. A method for preventing penetration of metal atoms or ions, or precursors thereof, from a metallization layer during the deposition of the metallization layer onto a porous substrate, the method comprising:
depositing a parylene containing polymeric film having a typical thickness in a range from 1.1 nm to 3.5 nm onto a porous substrate; and
depositing the metallization layer from a metal or metallorganic precursor onto the polymeric film.

12. A method for preventing penetration according to claim 11, wherein the polymeric film comprises repeating units derived from p-xylylene, phenylene vinyl, phenylene ethynylene, 1,4-methylene naphthalene, 2,6-methylene naphthalene, 1,4-vinylene naphthalene, 2,6-vinylene naphthalene, 1,4-ethynylene naphthalene, 2,6-ethynylene naphthalene, and substituted counterparts.

13. A method according to claim 12, wherein the polymeric film comprises repeating units selected from:

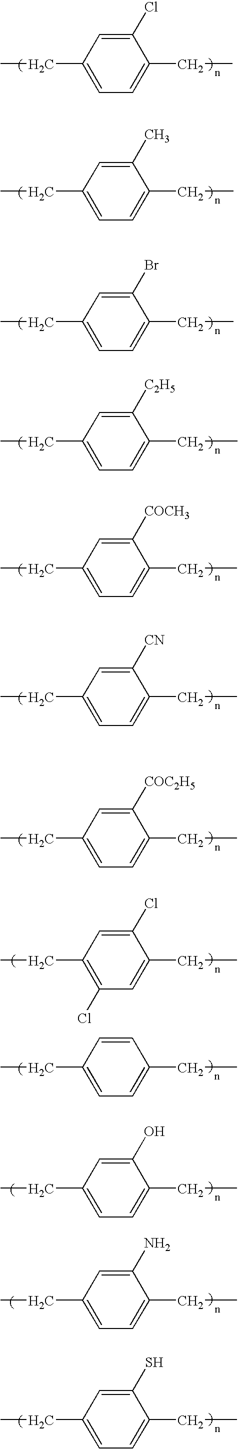

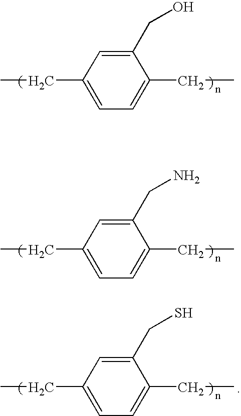

14. A method according to claim 11, wherein the metallization layer comprises tungsten, tungsten nitride, tantalum, tantalum nitride, copper, cobalt, cobalt tungsten phosphide, cobalt tungsten boride, nickel, nickel boride, and combinations thereof.

15. A method according to claim 11, wherein after the deposition of the metallization layer onto the porous substrate the increase in the effective dielectric constant value of the porous substrate and the polymeric film is less than 10% from the dielectric constant of the porous substrate alone.

16. A method for controlling the effective dielectric constant of a porous interlayer dielectric (ILD) comprising:
depositing a parylene containing polymeric film having a typical thickness in a range from 1.1 nm to 3.5 nm at a pressure selected from 1 millitorr to 8 millitorr and in the presence of a carrier gas selected from argon, helium, and nitrogen onto the porous ILD; and
depositing a metallization layer from a metal or metallorganic precursor onto the polymeric film.

17. A method according to claim 16, wherein after the deposition of the metallization layer onto the porous substrate the increase in the effective dielectric constant value of the porous substrate and the polymeric film is less than 10% from the dielectric constant of the porous substrate alone.

18. An integrated circuit comprising:
one or more integrated circuit components; and
an interlayer dielectric (ILD) having directly thereon (1) a parylene containing polymeric film having a typical thickness in a range from 1.1 nm to 3.5 nm and (2) a metal layer over the polymeric film.
